(19) United States
(12) Patent Application Publication
(10) Pub. No.: US 2026/0231768 A1
(43) Pub. Date: Aug. 6, 2026

(54) SEMICONDUCTOR DEVICE AND METHOD FOR MANUFACTURING SEMICONDUCTOR PACKAGE AND SEMICONDUCTOR DEVICE

(71) Applicant: SONY SEMICONDUCTOR SOLUTIONS CORPORATION, KANAGAWA (JP)

(72) Inventors: WENSHUANG DONG, KANAGAWA (JP); NAOKI KAKOIYAMA, KANAGAWA (JP); YASUSHI OTSUKA, KANAGAWA (JP)

(21) Appl. No.: 19/150,273

(22) PCT Filed: Dec. 7, 2023
(86) PCT No.: PCT/JP2023/043772

§ 371 Date: Jul. 23, 2025

(30) Foreign Application Priority Data
Feb. 1, 2023 (JP) 2023-013705

(51) Int. Cl. H10W 40/73; H10W 40/00; H10W 90/00

(52) U.S. Cl. CPC H10W 40/73; H10W 40/037; H10W 90/724; H10W 90/754

(57) ABSTRACT

A semiconductor device in which a semiconductor chip is provided improves a heat dissipation performance. The semiconductor device includes a semiconductor package, a heat dissipation member, and a connection member. In the semiconductor package, the semiconductor chip and a wiring substrate are provided. In the semiconductor package, the wiring substrate evaporates liquid by heat generated in the semiconductor chip and generates gas. In the semiconductor device, the heat dissipation member condenses gas into liquid. In the semiconductor device, the connection member supplies gas to the heat dissipation member and refluxes liquid to the wiring substrate.

### TECHNICAL FIELD

The present technology relates to a semiconductor device. Particularly, the present technology relates to a semiconductor device having a cooling function and a method for manufacturing a semiconductor package and the semiconductor device.

### BACKGROUND ART

Typically, in a semiconductor chip having large power consumption such as an image sensor, heat generated at the time of operation adversely affects a performance. Therefore, heat management is required. For example, an imaging device has been proposed in which a heat dissipation block having a passage therein and a fan that sucks and supplies air to and from the passage are arranged (for example, refer to Patent Document 1).

### CITATION LIST

### Patent Document

Patent Document 1: Japanese Patent Application Laid-Open No. 2005-207906

### SUMMARY OF THE INVENTION

### Problems to Be Solved by the Invention

In the related art described above, air cooling is performed with a fan so as to achieve appropriate temperature management. However, in the device described above, when an amount of heat generated in a semiconductor chip increases with improvement in a performance of the device and an increase in a processing amount, there is a possibility that a heat dissipation performance becomes insufficient. If a size of the fan or a heat dissipation block is increased, the heat dissipation performance can be improved. However, this is not preferable because a size of the device increases.

The present technology has been made in view of such a situation, and an object is to improve a heat dissipation performance in a semiconductor device in which a semiconductor chip is provided.

### Solutions to Problems

The present technology has been made to solve the above problem, and a first aspect of the present technology is a semiconductor device including a semiconductor package in which a semiconductor chip and a wiring substrate that evaporates liquid by heat generated in the semiconductor chip and generates gas are provided, a heat dissipation member that condenses the gas into the liquid, and a connection member that supplies the gas to the heat dissipation member and refluxes the liquid to the wiring substrate, and a method for manufacturing the semiconductor device. This brings about an effect of improving a heat dissipation performance.

Furthermore, in the first aspect, the wiring substrate may include a pair of substrates and a vapor chamber arranged between the pair of substrates. This brings about an effect of improving the heat dissipation performance.

Furthermore, in the first aspect, the wiring substrate may further include a mold resin formed around the vapor chamber. This brings about an effect of improving the heat dissipation performance.

Furthermore, in the first aspect, a counterbore hole may be formed in one of the pair of substrates, and the semiconductor chip may be bonded to the vapor chamber via the counterbore hole. This brings about an effect of further improving the heat dissipation performance.

Furthermore, in the first aspect, the vapor chamber may include a gas flow path, a liquid flow path, and a through-hole formed around the gas flow path and the liquid flow path. This brings about an effect that the mold resin becomes unnecessary.

Furthermore, in the first aspect, the semiconductor chip may be connected to the wiring substrate by wire bonding. This brings about an effect of electrically connecting the semiconductor chip.

Furthermore, in the first aspect, the semiconductor chip may be flip-chip mounted on the wiring substrate. This brings about an effect that wire bonding becomes unnecessary.

Furthermore, in the first aspect, the wiring substrate may include a pair of substrates and a heat pipe arranged between the pair of substrates. This brings about an effect of reducing manufacturing cost.

Furthermore, a second aspect of the present technology is a semiconductor package that includes a semiconductor chip and a wiring substrate that evaporates liquid by heat generated in the semiconductor chip and generates gas. This brings about an effect of improving a heat dissipation performance of the semiconductor package.

Furthermore, in the second aspect, the wiring substrate may evaporate liquid by the heat and generate gas and condense the gas and generate the liquid. This brings about an effect that the heat pipe and a heat sink become unnecessary.

### BRIEF DESCRIPTION OF DRAWINGS

FIG. 1 is an example of a cross-sectional view of a semiconductor device according to a first embodiment of the present technology.

FIG. 2 is a diagram for explaining a cooling function of the semiconductor device according to the first embodiment of the present technology.

FIG. 3 is a block diagram depicting one configuration example of the semiconductor device according to the first embodiment of the present technology.

FIG. 4 is a diagram for explaining a manufacturing process of a part of a vapor chamber according to the first embodiment of the present technology.

FIG. 5 is a diagram for explaining a manufacturing process of a lower substrate according to the first embodiment of the present technology.

FIG. 6 is a diagram for explaining a manufacturing process of a semiconductor package according to the first embodiment of the present technology.

FIG. 7 is an example of a cross-sectional view of a layer of a mold resin immediately after dicing according to the first embodiment of the present technology.

FIG. 8 is a diagram for explaining a manufacturing process of the semiconductor device according to the first embodiment of the present technology.

FIG. 9 is flowchart depicting an example of the manufacturing process of the semiconductor device according to the first embodiment of the present technology.

FIG. 10 is an example of a cross-sectional view of a semiconductor package according to a comparative example.

FIG. 11 is a diagram depicting a comparison result of various performances between the first embodiment and the comparative example of the present technology.

FIG. 12 is a diagram for explaining a manufacturing process according to a modification of the first embodiment of the present technology.

FIG. 13 is an example of a cross-sectional view of a semiconductor device according to a second embodiment of the present technology.

FIG. 14 is a diagram for explaining a manufacturing process of a wiring substrate according to the second embodiment of the present technology.

FIG. 15 is a diagram for explaining a manufacturing process of the semiconductor device according to the second embodiment of the present technology.

FIG. 16 is an example of a cross-sectional view of a semiconductor package according to a third embodiment of the present technology.

FIG. 17 is an example of a cross-sectional view of a semiconductor device according to a fourth embodiment of the present technology.

FIG. 18 is a diagram for explaining a manufacturing process of a wiring substrate according to the fourth embodiment of the present technology.

FIG. 19 is a diagram for explaining a manufacturing process of the semiconductor device according to the fourth embodiment of the present technology.

FIG. 20 is an example of a cross-sectional view of a semiconductor device according to a fifth embodiment of the present technology.

FIG. 21 is an example of a cross-sectional view of the semiconductor device viewed from a different direction, according to the fifth embodiment of the present technology.

FIG. 22 is an example of a cross-sectional view of a semiconductor device according to a sixth embodiment of the present technology.

FIG. 23 is an example of a cross-sectional view of a semiconductor device according to a seventh embodiment of the present technology.

FIG. 24 is a block diagram depicting a schematic configuration example of a vehicle control system.

FIG. 25 is an explanatory diagram depicting an example of installation positions of imaging sections.

### MODE FOR CARRYING OUT THE INVENTION

Modes for carrying out the present technology (hereinafter, referred to as embodiments) will be described below. The description will be given in the following order.
1. First Embodiment (example in which vapor chamber is arranged in wiring substrate)
2. Second Embodiment (example in which vapor chamber is arranged in wiring substrate and counterbore hole is formed)
3. Third Embodiment (example in which vapor chamber is arranged in wiring substrate and heat pipe and heat sink are removed)
4. Fourth Embodiment (example in which vapor chamber is arranged in wiring substrate and mold resin is removed)
5. Fifth Embodiment (example in which vapor chamber is arranged in wiring substrate and semiconductor chip is flip-chip mounted)
6. Sixth Embodiment (example in which vapor chamber is arranged in wiring substrate, mold resin is removed, and counterbore hole is not formed)
7. Seventh Embodiment (example in which heat pipe is arranged in wiring substrate)
8. Application Example to Mobile Object

### 1. First Embodiment

### Configuration Example of Semiconductor Device

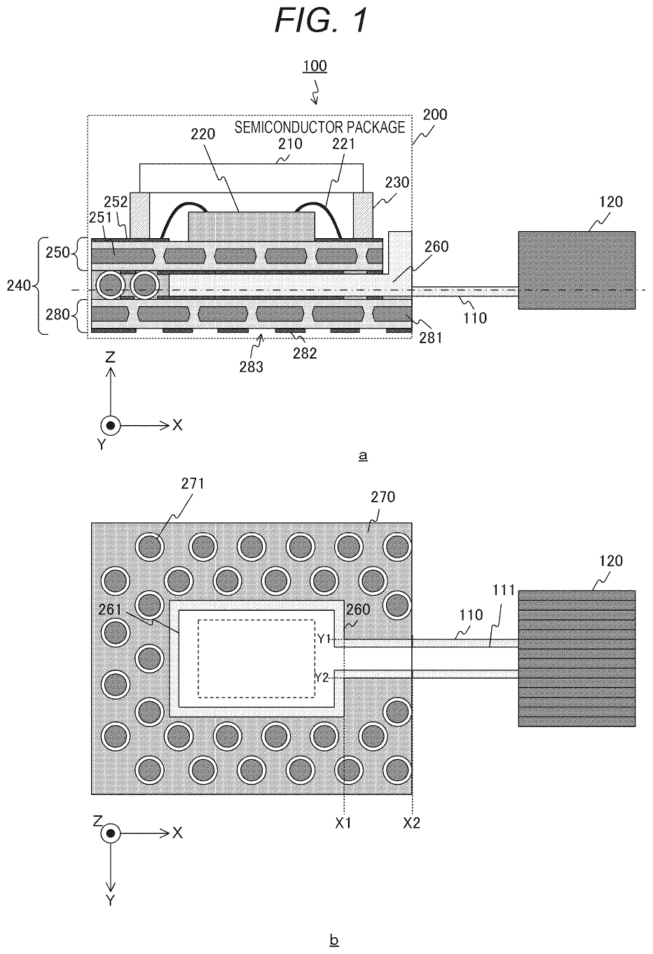

FIG. 1 is a cross-sectional view depicting one configuration example of a semiconductor device 100 according to an embodiment of the present technology. In FIG. 1, a is an example of the cross-sectional view of the semiconductor device 100 as viewed from a direction parallel to a substrate plane of a wiring substrate 240. In FIG. 1, b is an example of the cross-sectional view of the semiconductor device 100 as viewed from a direction perpendicular to the substrate plane of the wiring substrate 240, taken along an alternate long and short dash line in a of FIG. 1. As the semiconductor device 100, for example, a smartphone, a personal computer, a digital camera, and the like having an imaging function are exemplified.

As depicted in a of FIG. 1, the semiconductor device 100 includes a semiconductor package 200, a heat pipe 110, and a heat sink 120. The semiconductor package 200 includes glass 210, a semiconductor chip 220, a frame 230, and the wiring substrate 240.

Hereinafter, a predetermined axis parallel to the substrate plane of the wiring substrate 240 is set as an “X axis”, and an axis perpendicular to the substrate plane is set as a “Z axis”. An axis parallel to the X axis and the Z axis is set as a “Y axis”. In FIG. 1, a is a cross-sectional view viewed from the Y axis direction.

Furthermore, a direction from the wiring substrate 240 toward the semiconductor chip 220 is set as an “upward” direction. A top surface of the wiring substrate 240 is flat, and the semiconductor chip 220 is electrically connected to the top surface with a wire 221. For example, as the semiconductor chip 220, CMOS image sensors (CIS) are used.

The frame 230 has a frame shape as viewed from the Z axis direction, and a lower surface thereof is connected to the top surface of the wiring substrate 240 so as to surround the semiconductor chip 220. The glass 210 is mounted on a top surface of the frame 230.

The wiring substrate 240 includes an upper substrate 250 and a lower substrate 280 and a vapor chamber 260 arranged therebetween. The lower substrate 280 includes a core material 281, and a copper foil 282 is formed on a lower surface thereof. In this copper foil 282, a predetermined number of copper plating holes 283 used to mount solder balls are provided. The upper substrate 250 includes a core material 251, and a copper foil 252 is formed on a top surface thereof. Note that the upper substrate 250 and the lower substrate 280 are an example of a pair of substrates described in claims.

Furthermore, as depicted in b of FIG. 1, an area of the vapor chamber 260 as viewed from the Z axis direction is smaller than an area of each of the upper substrate 250 and the lower substrate 280. A mold resin 270 is formed around the vapor chamber 260. The mold resin 270 includes a predetermined number of solder balls 271, and this solder ball 271 electrically connects the upper substrate 250 and the lower substrate 280.

Furthermore, the vapor chamber 260 is arranged immediately below the semiconductor chip 220. A dotted rectangle in b of FIG. 1 indicates a position of the semiconductor chip 220.

The vapor chamber 260 includes a gas flow path 261 and a liquid flow path (not depicted) having a capillary structure. The heat pipe 110 also includes a gas flow path 111 and a liquid flow path (not depicted) having the capillary structure. Furthermore, the vapor chamber 260 includes a main body portion and a vent having one end opening to a side surface of the wiring substrate 240. A portion surrounded by coordinates X1, X2, Y1, and Y2 in FIG. 1 corresponds to the vent, and a portion other than the vent corresponds to the main body portion.

Portions of the vents of the gas flow path 261 and the liquid flow path in the vapor chamber 260 are connected to the gas flow path 111 and the liquid flow path in the heat pipe 110. Note that, in a of FIG. 1, for convenience of description, the gas flow paths 261 and 111 in b of FIG. 1 are omitted.

One end of the heat pipe 110 is joined to the vent of the vapor chamber 260, and another end is joined to the heat sink 120.

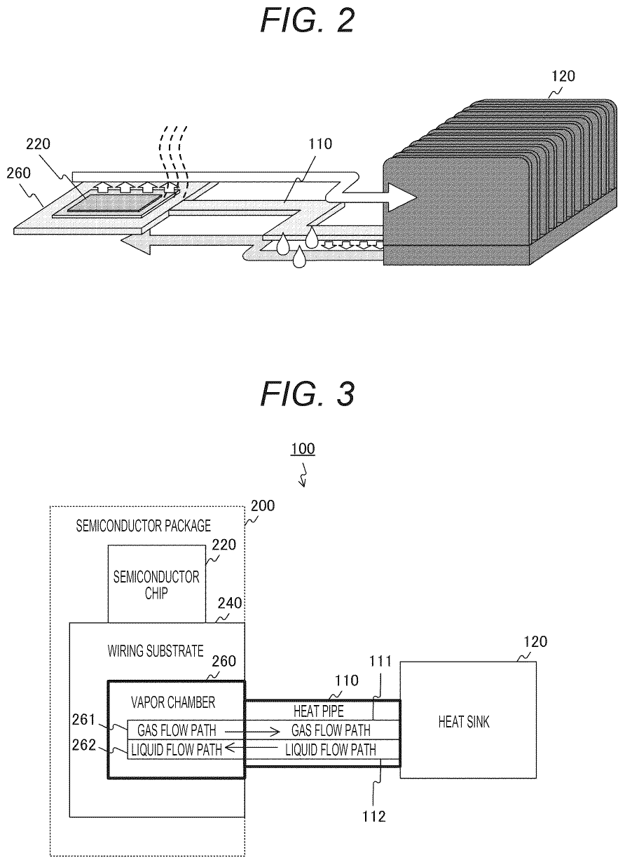

FIG. 2 is a diagram for explaining a cooling function of the semiconductor device 100 according to the first embodiment of the present technology. As power consumption of the semiconductor chip 220 increases, heat at the time of operation adversely affects a performance. Therefore, it is necessary to manage the heat.

As described above, the gas flow path and the liquid flow path are formed in the vapor chamber 260. The heat generated in the semiconductor chip 220 causes liquid (water or the like) to evaporate and generates gas (water vapor or the like), in the gas flow path in the vapor chamber 260. The gas is supplied to the heat sink 120 via the gas flow path in the heat pipe 110, by diffusion. The heat sink 120 condenses gas into liquid, for example, by natural air cooling. The liquid is refluxed to the liquid flow path in the vapor chamber 260 by a capillary action, through the liquid flow path in the heat pipe 110 having the capillary structure. As a result, the semiconductor chip 220 is efficiently cooled.

Furthermore, since the heat sink 120 is arranged at a place away from immediately below the semiconductor chip 220, a condensation function of evaporation and condensation becomes unnecessary in the vapor chamber 260, and the area of the vapor chamber 260 can be reduced for that.

Note that, although natural air cooling is performed by the heat sink 120, it is possible to provide a fan instead of the heat sink and perform forced air cooling. Furthermore, both of the heat sink 120 and the fan can be provided.

Furthermore, the heat pipe 110 is an example of a connection member described in claims, and the heat sink 120 and the fan are examples of a heat dissipation member described in claims.

FIG. 3 is a block diagram depicting one configuration example of the semiconductor device 100 according to the first embodiment of the present technology. The wiring substrate 240 immediately below the semiconductor chip 220 includes the vapor chamber 260 therein, and the gas flow path 261 and a liquid flow path 262 are provided in the vapor chamber 260. Furthermore, the gas flow path 111 and a liquid flow path 112 are provided in the heat pipe 110.

The gas flow path 261 is connected to the gas flow path 111, and the liquid flow path 262 is connected to the liquid flow path 112. Gas is supplied to the heat sink 120 via these gas flow paths 261 and 111, and liquid is refluxed to the vapor chamber 260 via the liquid flow paths 262 and 112.

### Method for Manufacturing Semiconductor Device

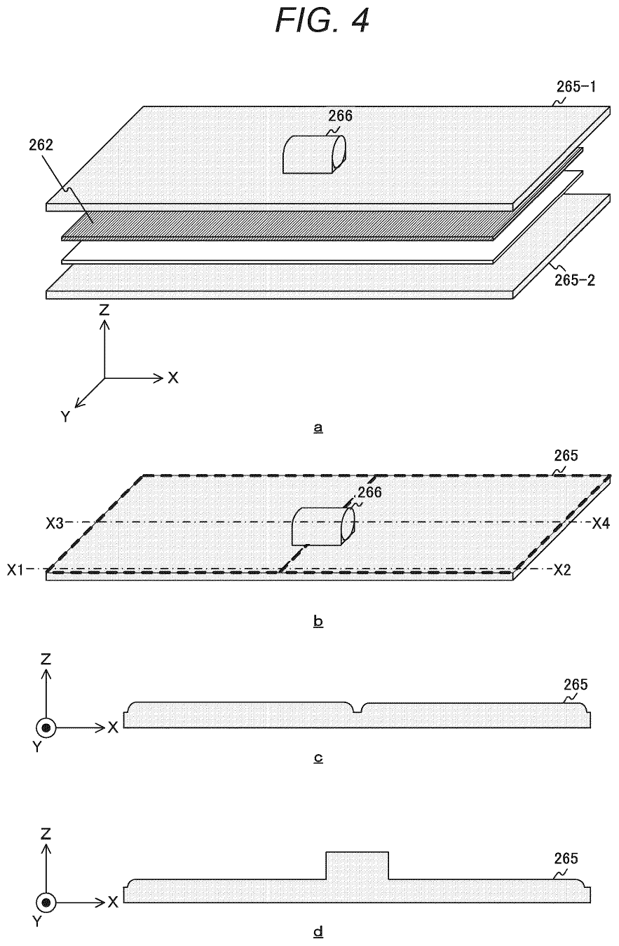

FIG. 4 is a diagram for explaining a manufacturing process of a part of the vapor chamber 260 according to the first embodiment of the present technology.

First, as depicted in a of FIG. 4, a top cover 265-1 and a bottom cover 265-2 are connected with the liquid flow path 262 having the capillary structure sandwiched therebetween, by stamping or the like. On a top surface of the top cover 265-1, a vent 266 is formed in advance.

As a result, as depicted in b of FIG. 4, an upper lid 265 is obtained. In FIG. 4, c is an example of a cross-sectional view of the upper lid 265 viewed from the Y axis direction, taken along a line X1-X2 in b of FIG. 4. In FIG. 4, d is an example of a cross-sectional view of the upper lid 265 viewed from the Y axis direction, taken along a line X3-X4 in b of FIG. 4.

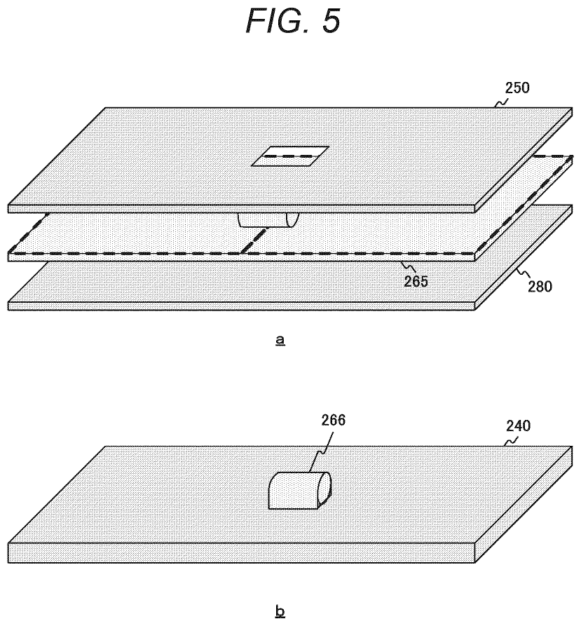

FIG. 5 is a diagram for explaining a manufacturing process of the lower substrate 280 according to the first embodiment of the present technology. After the process in FIG. 4, as depicted in a of FIG. 5, the upper substrate 250 and the lower substrate 280 are connected with the upper lid 265 sandwiched therebetween, by stamping or the like. As a result, as depicted in b of FIG. 5, the wiring substrate 240 is obtained.

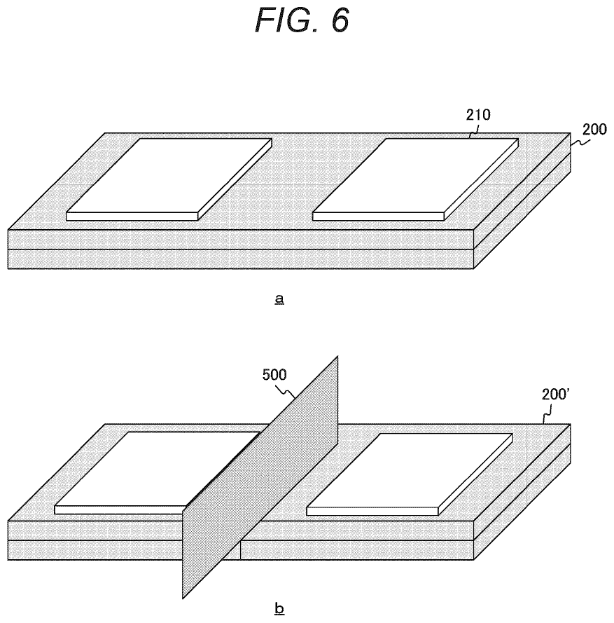

FIG. 6 is a diagram for explaining a manufacturing process of the semiconductor package 200 according to the first embodiment of the present technology.

As depicted in a of FIG. 6, sealing is performed with a mold resin. Then, the semiconductor chip 220 is connected, and the frame 230 and the glass 210 are mounted. In FIG. 6, the molded layer and the semiconductor chip 220 and the frame 230 are omitted, for convenience of description.

As a result, as depicted in b of FIG. 6, the semiconductor package 200 is obtained. By dicing the semiconductor package 200 with a dicing saw 500, a plurality of package components is obtained.

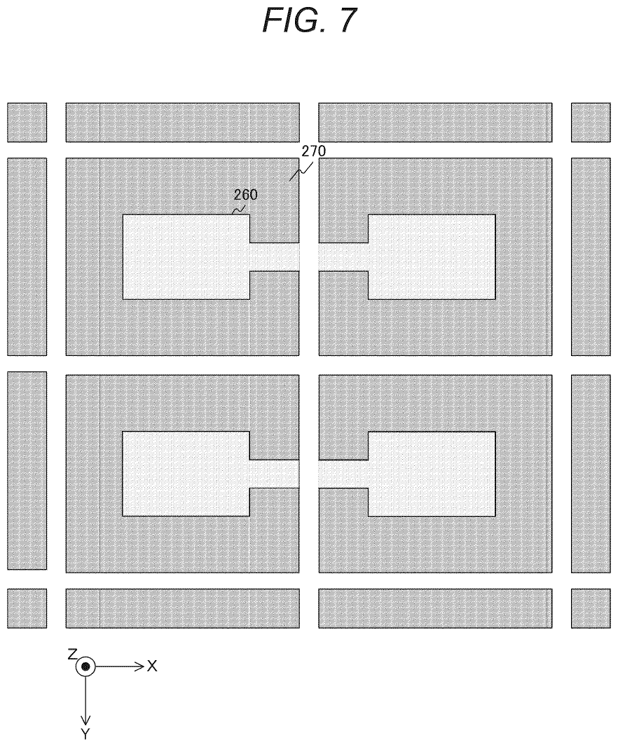

FIG. 7 is an example of a cross-sectional view of a layer of the mold resin 270 viewed from the Z axis direction, immediately after dicing. As depicted in FIG. 7, the plurality of vapor chambers 260 is obtained by dicing.

As depicted in FIGS. 4 to 7, the process for manufacturing the wiring substrate 240 including the vapor chamber 260 therein to the process for connecting the semiconductor chip 220 or the like are performed before dicing. As a result, manufacturing is facilitated, as compared with a case where the vapor chamber 260 is provided after dicing.

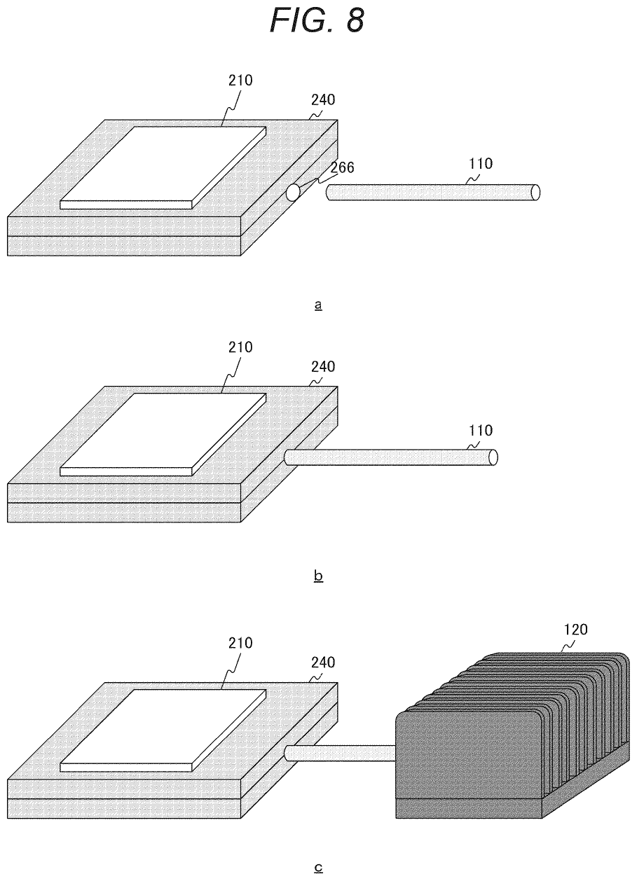

FIG. 8 is a diagram for explaining a manufacturing process of the semiconductor device 100 according to the first embodiment of the present technology. After the process in FIG. 6, as depicted in a and b of FIG. 8, one end of the heat pipe 110 is joined to the vent 266. Then, as depicted in c of FIG. 8, the heat sink 120 is joined to another end of the heat pipe 110. As a result, the semiconductor device 100 depicted in FIG. 1 is obtained.

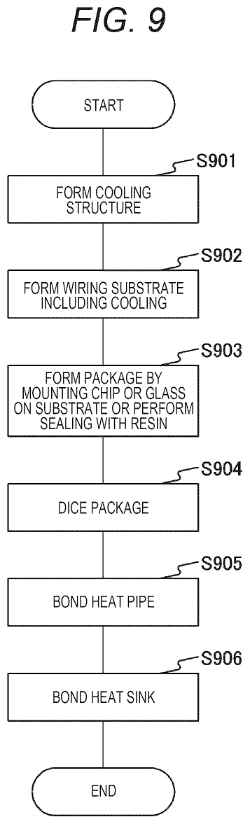

FIG. 9 is a flowchart depicting an example of the manufacturing process of the semiconductor device 100 according to the first embodiment of the present technology. First, a cooling structure that includes the liquid flow path having the capillary structure is formed (step S901), and the wiring substrate 240 including the cooling structure therein is formed (step S902). Subsequently, the semiconductor package 200 is formed by mounting the semiconductor chip 220, the frame 230, and the glass 210 on the substrate and performing sealing using the mold resin 270 (step S903).

Then, by dicing the semiconductor package 200, a plurality of package components 200′ is obtained (step S904). For each package component 200′, one end of the heat pipe 110 is joined (step S905), and the heat sink 120 is joined to another end thereof (step S906). After step S906, various subsequent processes are performed as necessary, and the manufacturing process of the semiconductor device 100 ends.

Here, the semiconductor package 200 having a configuration in which the heat sink 120 is arranged below the semiconductor chip 220, without using the vapor chamber 260 is assumed as a comparative example.

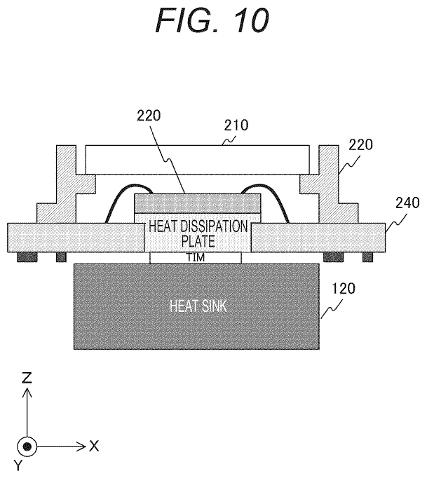

FIG. 10 is an example of a cross-sectional view of the semiconductor package according to the comparative example. In this comparative example, the vapor chamber 260 is not included in the wiring substrate 240. Furthermore, immediately below the semiconductor chip 220, the wiring substrate 240 is opened, a heat dissipation plate passing through the wiring substrate 240 is connected to a lower surface of the semiconductor chip 220. As a material of the heat dissipation plate, for example, copper-tungsten (CuW) is used. Furthermore, a lower surface of the heat dissipation plate is connected to the heat sink 120 therebelow, via a thermal interface material (TIM).

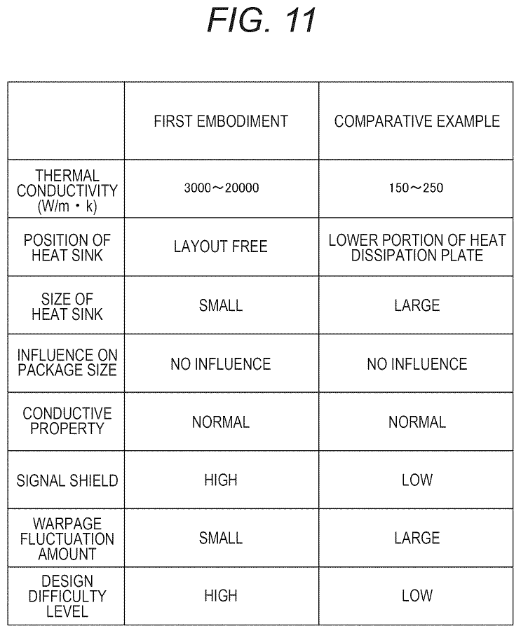

FIG. 11 is diagram depicting a comparison result of various performances between the first embodiment and the comparative example of the present technology. In the first embodiment, since an intermediate member such as the heat dissipation plate or the TIM in the comparative example is removed and heat is conducted by a liquid refrigerant, a heat conduction efficiency can be improved as compared with the comparative example. For example, a thermal conductivity in the first embodiment is 3000 to 20000 W/m·k, whereas a thermal conductivity in the comparative example is 150 to 250 W/m·k.

Furthermore, in the first embodiment, since the heat dissipation member such as the heat sink 120 is provided outside the semiconductor package 200, there is no limitation on an arrangement place. A position of the heat dissipation member is not limited to a side surface of the semiconductor chip 220 and can be arranged on a top surface of the semiconductor chip 220. On the other hand, in the comparative example, the heat dissipation member is limited to a lower side of the heat dissipation plate.

Furthermore, in the first embodiment, since the heat conduction efficiency is high, a size of the heat dissipation member (heat sink 120 or the like) can be made smaller than that in the comparative example.

Furthermore, since the vapor chamber 260 in the wiring substrate 240 acts as a metal core, an effect of a signal shield becomes higher than that in the comparative example.

Furthermore, in the first embodiment, as a material of the vapor chamber 260, Cu/Al/Ti, or the like can be used, and a middle protrusion core structure can be provided therein. As a result, it is possible to prevent thermal deformation of the entire wiring substrate 240 and to reduce a variation amount of warpage of the semiconductor package 200 as compared with the comparative example. Furthermore, by using Cu as a metal core material of the vapor chamber 260, the vapor chamber 260 can be used as ground. As a result, it is possible to reduce a wiring area on the ground and stabilize signals.

Note that a design difficulty level of the first embodiment is higher than that of the comparative example.

In addition, although not depicted in FIG. 11, in the first embodiment, a heat capacity of the vapor chamber 260 is large. Therefore, a temperature change amount decreases, and reliability can be improved in a test under a high temperature and low temperature environment. Furthermore, since the temperature change amount is small, the area of the heat dissipation member can be reduced, and the size can be reduced.

In this way, according to the first embodiment of the present technology, since liquid is evaporated in the vapor chamber 260 in the wiring substrate 240 and is supplied to the heat sink 120 via the heat pipe 110, a heat dissipation performance can be improved as compared with the comparative example.

### Modification

In the first embodiment, the process for manufacturing the wiring substrate 240 including the vapor chamber 260 therein is performed before dicing. However, the vapor chamber 260 can be formed after dicing. A modification of the first embodiment is different from the first embodiment in a method for forming the vapor chamber 260.

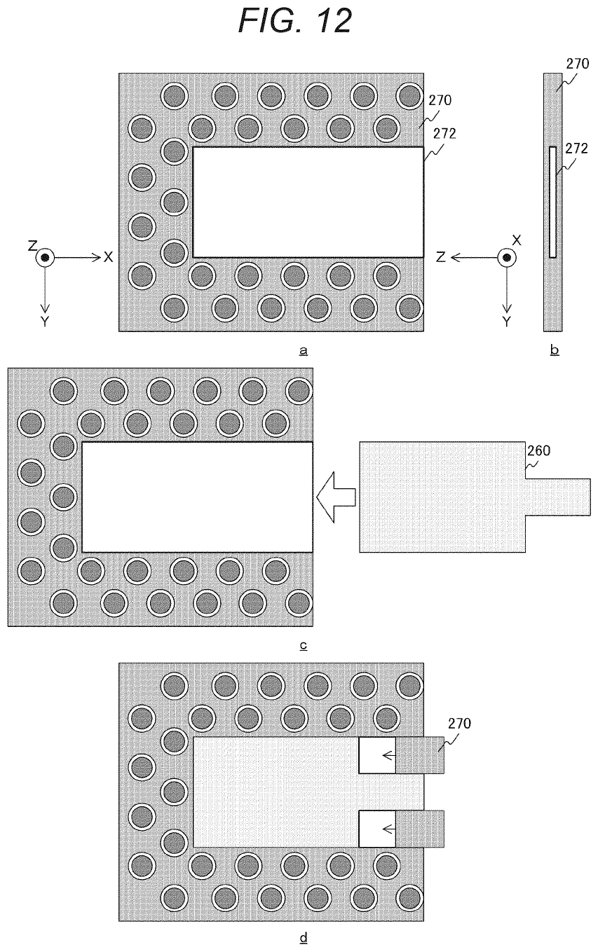

FIG. 12 is a diagram for explaining a manufacturing process according to the modification of the first embodiment of the present technology. As depicted in a of FIG. 12, a slit 272 is formed in the mold resin 270, after dicing. Note that the vapor chamber 260 is not formed, before dicing. In FIG. 12, b is a cross-sectional view of the layer of the mold resin 270 viewed from the X axis direction.

Then, as depicted in c of FIG. 12, the vapor chamber 260 is inserted into the slit 272. Next, as depicted in d of FIG. 12, a remainder of the slit 272 is embedded with the mold resin 270.

As depicted in FIG. 12, by inserting the vapor chamber 260 after dicing, the manufacturing process of the wiring substrate 240 and the manufacturing process of the vapor chamber 260 can be separated.

In this way, according to the modification of the first embodiment of the present technology, since the vapor chamber 260 is inserted after dicing, the manufacturing process of the wiring substrate 240 and the manufacturing process of the vapor chamber 260 can be separated.

### 2. Second Embodiment

Although the semiconductor chip 220 is connected to the flat top surface of the upper substrate 250 in the first embodiment, it is preferable that the lower surface of the semiconductor chip 220 and the vapor chamber 260 be close to each other. A semiconductor device 100 according to the second embodiment is different from the first embodiment in that a counterbore hole is formed in the upper substrate 250 and the semiconductor chip 220 is arranged on its bottom surface.

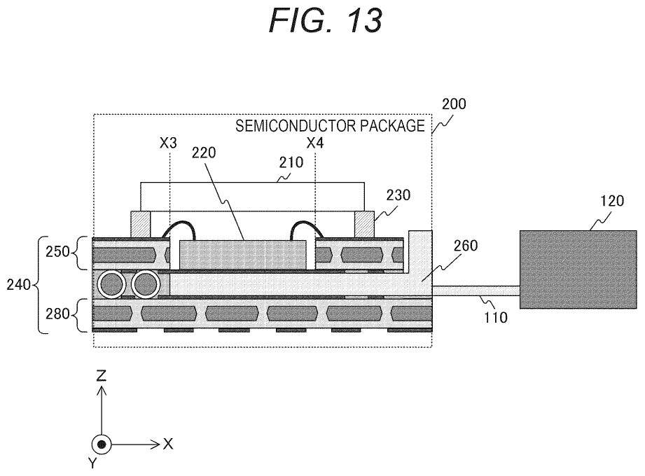

FIG. 13 is an example of a cross-sectional view of the semiconductor device 100 according to the second embodiment of the present technology. The semiconductor device 100 according to the second embodiment is different from the first embodiment in that, in a region from coordinates X3 to X4 in the upper substrate 250, the counterbore hole passing through the substrate is formed. The lower surface of the semiconductor chip 220 is bonded to a top surface of the vapor chamber 260, via the counterbore hole. As depicted in FIG. 13, since the semiconductor chip 220 is directly bonded to the vapor chamber 260, a heat dissipation performance can be improved as compared with the first embodiment.

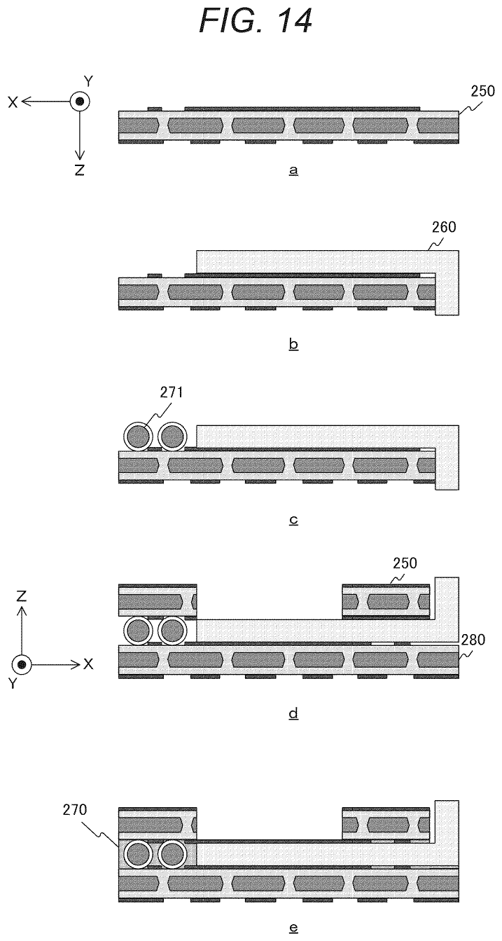

FIG. 14 is a diagram for explaining a manufacturing process of a wiring substrate 240 according to the second embodiment of the present technology. As depicted in a of FIG. 14, the upper substrate 250 is formed, and as depicted in b of FIG. 14, the upper substrate 250 is joined to the vapor chamber 260. Then, as depicted in c of FIG. 14, a solder ball 271 is mounted.

Subsequently, as depicted in d of FIG. 14, the upper substrate 250 and the vapor chamber 260 are vertically inverted and are mounted on a lower substrate 280, and the counterbore hole is formed in the upper substrate 250. Then, as depicted in e of FIG. 14, a mold resin 270 is injection molded.

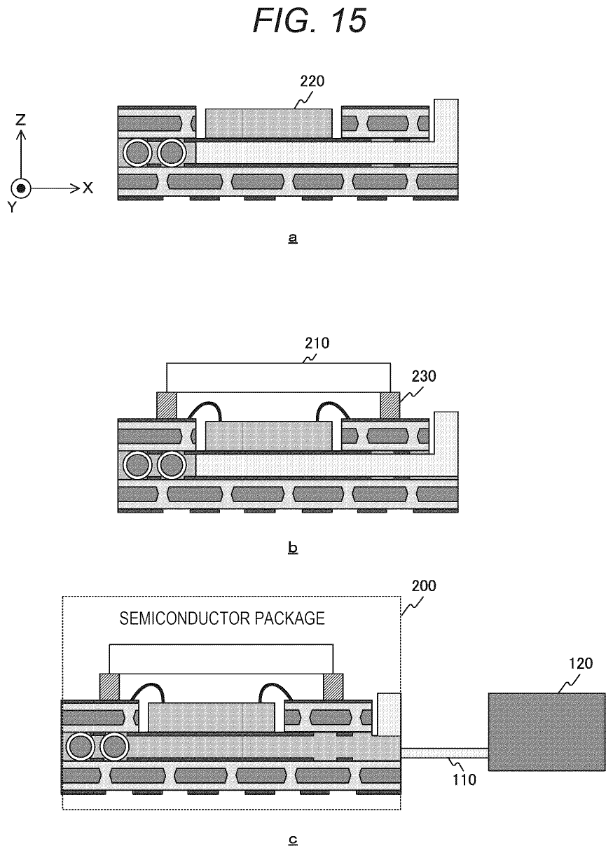

FIG. 15 is a diagram for explaining a manufacturing process of the semiconductor device 100 according to the second embodiment of the present technology. After the process in FIG. 14, as depicted in a of FIG. 15, the semiconductor chip 220 is arranged on a bottom surface of the counterbore hole and is bonded to the vapor chamber 260. As depicted in b of FIG. 15, the semiconductor chip 220 is wire bonded, and a frame 230 and glass 210 are mounted. At this time, a vent of the vapor chamber 260 is cut by water jet, and inside thereof is filled with liquid.

Then, as depicted in c of FIG. 15, one end of a heat pipe 110 is joined to a semiconductor package 200, and a heat sink 120 is joined to another end.

In this way, according to the second embodiment of the present technology, since the semiconductor chip 220 is bonded to the vapor chamber 260 via the counterbore hole in the upper substrate 250, the heat dissipation performance can be improved as compared with the first embodiment.

### 3. Third Embodiment

In the first embodiment, the heat sink 120 is connected by the heat pipe 110, and cooling is performed by the heat sink 120. However, this configuration needs a process for joining the heat pipe 110 and the heat sink 120. A semiconductor device 100 according to a third embodiment is different from the first embodiment in that the heat pipe 110 and the heat sink 120 are removed.

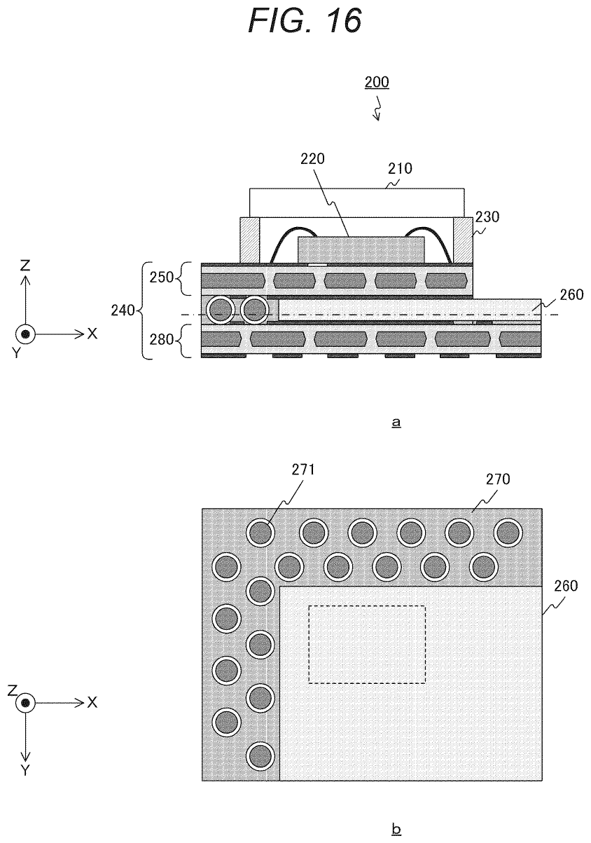

FIG. 16 is an example of a cross-sectional view of a semiconductor package 200 according to the third embodiment of the present technology. In the semiconductor device 100 according to the third embodiment, the heat pipe 110 and the heat sink 120 are not arranged.

In FIG. 16, a is an example of a cross-sectional view of the semiconductor package 200 as viewed from the Y axis direction. In FIG. 16, b is an example of a cross-sectional view of the semiconductor package 200 as viewed from the Z axis direction, taken along an alternate long and short dash line in a of FIG. 16.

As depicted in a and b of FIG. 16, in the third embodiment, a vent is not provided in a vapor chamber 260, and a part of a top surface thereof is exposed. By natural cooling of the exposed surface, gas is condensed into liquid in the vapor chamber 260, and is refluxed to a direction immediately below a semiconductor chip 220.

By reducing the heat pipe 110 and the heat sink 120, it is possible to miniaturize the semiconductor device 100, reduce cost, and simplify a manufacturing process.

In this way, according to the third embodiment of the present technology, since the vapor chamber 260 itself condenses the gas, the heat pipe 110 and the heat sink 120 can be removed.

### 4. Fourth Embodiment

In the first embodiment, the mold resin 270 is formed around the vapor chamber 260. However, this configuration needs a molding process. A semiconductor device 100 according to a fourth embodiment is different from the first embodiment in that the mold resin 270 is removed.

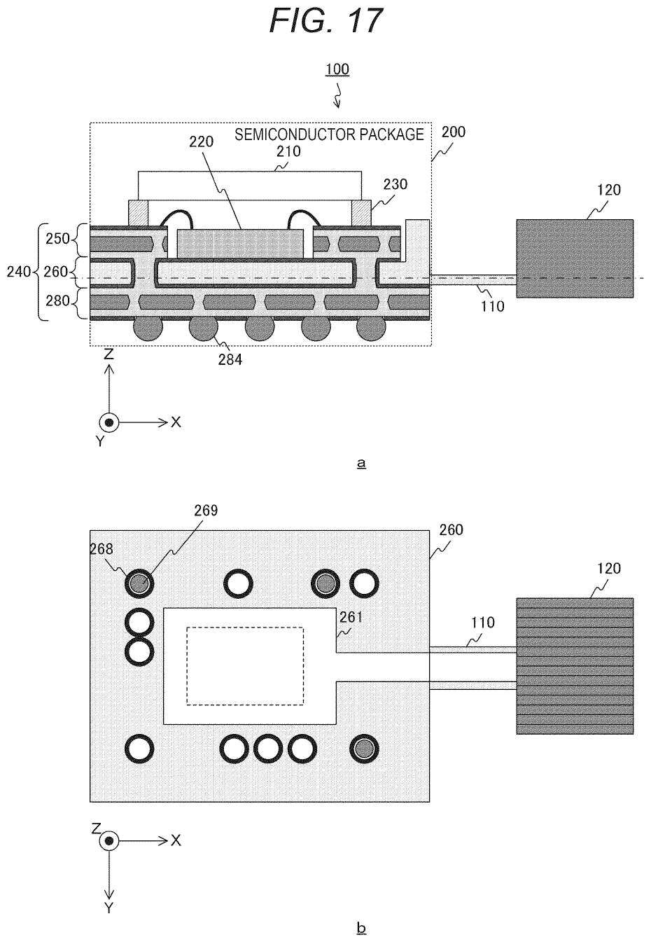

FIG. 17 is an example of a cross-sectional view of the semiconductor device 100 according to the fourth embodiment of the present technology. In FIG. 17, a is an example of a cross-sectional view of the semiconductor device 100 as viewed from the Y axis direction. In FIG. 17, b is an example of a cross-sectional view of the semiconductor device 100 as viewed from the Z axis direction, taken along an alternate long and short dash line in a of FIG. 17.

As depicted in a of FIG. 17, a vapor chamber 260 between an upper substrate 250 and a lower substrate 280 is arranged. Furthermore, as depicted in b of FIG. 17, an area of the vapor chamber 260 is about the same as the lower substrate 280, and the mold resin 270 around the vapor chamber 260 is removed. Furthermore, in the vapor chamber 260 a predetermined number of through-holes are formed around a gas flow path 261 and a liquid flow path (not depicted) therein. Copper plating 268 is applied to an inner periphery of the through-hole, and inside of the through-hole is filled with a resin 269. With these through-holes, the upper substrate 250 and the lower substrate 280 can be electrically connected.

Note that, unlike the first embodiment, since the through-hole is formed in the vapor chamber 260 itself, there is a concern that a thermal conductivity decreases accordingly. However, since an original thermal conductivity of the vapor chamber 260 is high, it is estimated that an influence is not so large.

Furthermore, in the fourth embodiment, in a similar manner as in the second embodiment, a counterbore hole is formed in the upper substrate 250, and a semiconductor chip 220 is arranged on its bottom portion.

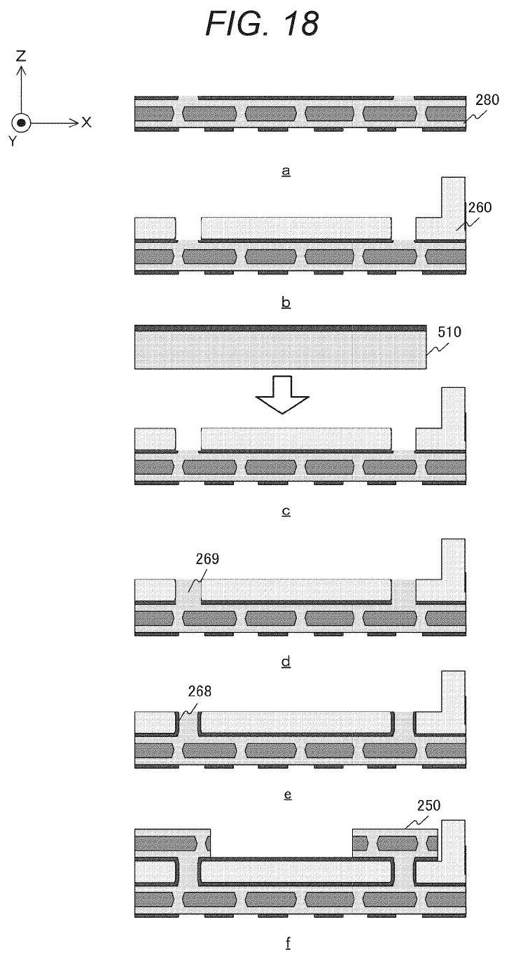

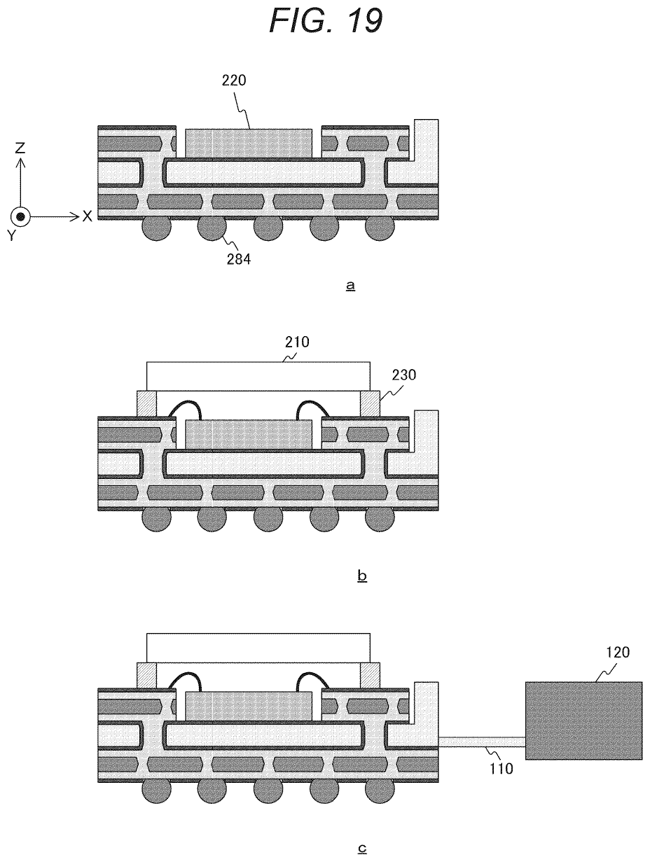

FIG. 18 is a diagram for explaining a manufacturing process of a wiring substrate 240 according to the fourth embodiment of the present technology. As depicted in a of FIG. 18, the lower substrate 280 is formed, and as depicted in b of FIG. 18, the vapor chamber 260 in which the through-hole is formed is joined.

Then, as depicted in c of FIG. 18, an insulating resin film 510 with a copper foil is pressed against the vapor chamber 260.

As a result, as depicted in d of FIG. 18, the through-hole is filled with the semi-cured resin 269. Then, after the resin 269 is completely cured by heating, a via hole is formed by a laser, and as depicted in e of FIG. 18, the copper plating 268 is applied to the inner periphery of the through-hole. Then, as depicted in f of FIG. 18, the upper substrate 250 is laminated, and the counterbore hole is formed.

As depicted in FIG. 18, by removing the mold resin 270, the molding process becomes unnecessary.

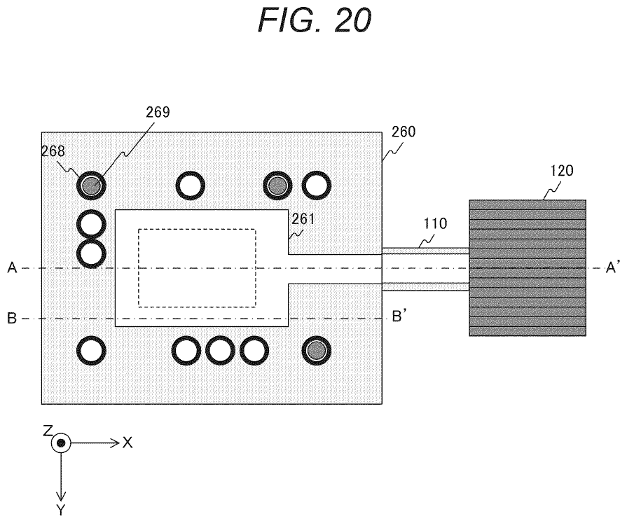

FIG. 19 is a diagram for explaining a manufacturing process of the semiconductor device 100 according to the fourth embodiment of the present technology. After the process in FIG. 18, as depicted in a of FIG. 19, the semiconductor chip 220 is arranged on the bottom portion of the counterbore hole. As depicted in b of FIG. 19, the semiconductor chip 220 is wire bonded, and a frame 230 and glass 210 are mounted.

Then, as depicted in c of FIG. 19, one end of a heat pipe 110 is joined to a semiconductor package 200, and a heat sink 120 is joined to another end.

In this way, according to the fourth embodiment of the present technology, since the mold resin 270 around the vapor chamber 260 is removed, the molding process becomes unnecessary.

### 5. Fifth Embodiment

In the fourth embodiment, the semiconductor chip 220 is wire bonded. However, a mounting method is not limited to this. A semiconductor device 100 according to a fifth embodiment is different from the fourth embodiment in that the semiconductor chip 220 is flip-chip mounted.

FIG. 20 is an example of a cross-sectional view of the semiconductor device viewed from the Z axis direction, according to the fifth embodiment of the present technology.

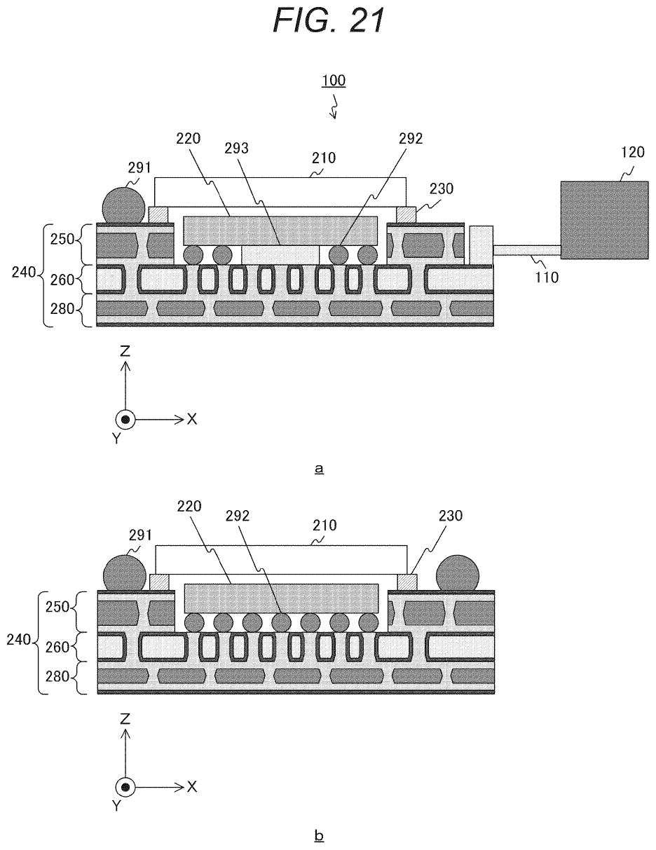

In FIG. 21, a is an example of a cross-sectional view of the semiconductor device 100 viewed from the Y axis direction, taken along a line A-A′ in FIG. 20. In FIG. 21, b is an example of a cross-sectional view of the semiconductor device 100 viewed from the Y axis direction, taken along a line B-B′ in FIG. 20.

As depicted in FIG. 21, a lower surface of the semiconductor chip 220 is flip-chip mounted on a top surface of a vapor chamber 260, with adhesive 293 and a solder ball 292. Furthermore, on a top surface of an upper substrate 250, a solder ball 291 is mounted around a frame 230, and is connected to outside via the solder ball 291.

As depicted in FIG. 21, by flip-chip mounting the semiconductor chip 220, wire bonding becomes unnecessary. Furthermore, with the solder ball 291, it is possible to cope with an application for mounting a top surface of a wiring substrate 240 outside. Moreover, a distance between a top surface of the semiconductor chip 220 and glass 210 can be shortened as compared with the fourth embodiment.

In this way, according to the fourth embodiment of the present technology, since the semiconductor chip 220 is flip-chip mounted, wire bonding becomes unnecessary.

### 6. Sixth Embodiment

In the fourth embodiment, the semiconductor chip 220 is bonded to the vapor chamber 260 via the counterbore hole in the upper substrate 250. However, the configuration is not limited to this. A semiconductor device 100 according to a sixth embodiment is different from the fourth embodiment in that the counterbore hole is not provided in the upper substrate 250 and the semiconductor chip 220 is wire bonded to a flat top surface.

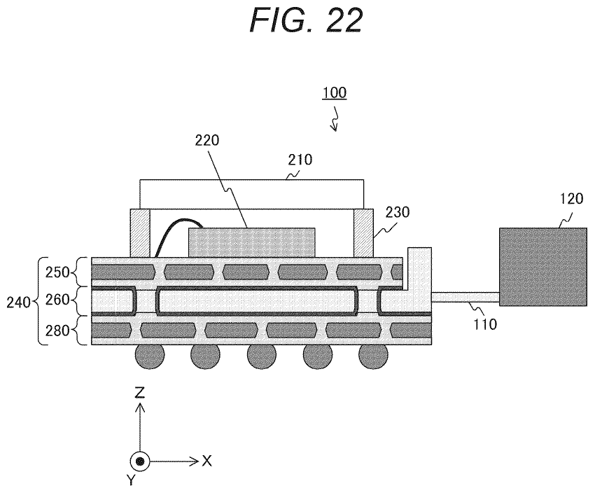

FIG. 22 is an example of a cross-sectional view of the semiconductor device 100 according to the sixth embodiment of the present technology. The semiconductor device 100 according to the sixth embodiment is different from that in the fourth embodiment in that the counterbore hole is not formed in the upper substrate 250 and the semiconductor chip 220 is wire bonded to the flat top surface. As a result, a counterbore hole forming process becomes unnecessary.

Furthermore, a distance between the semiconductor chip 220 and glass 210 can be shortened as compared with the fourth embodiment, and it is possible to cope with reverse bonding.

In this way, according to the sixth embodiment of the present technology, since the semiconductor chip 220 is wired bonded to the flat top surface of the upper substrate 250, the counterbore hole forming process becomes unnecessary.

### 7. Seventh Embodiment

In the first embodiment, liquid is evaporated by the vapor chamber 260. However, the configuration is not limited to this. A semiconductor device 100 according to a seventh embodiment is different from that in the first embodiment in that a heat pipe is used instead of the vapor chamber 260.

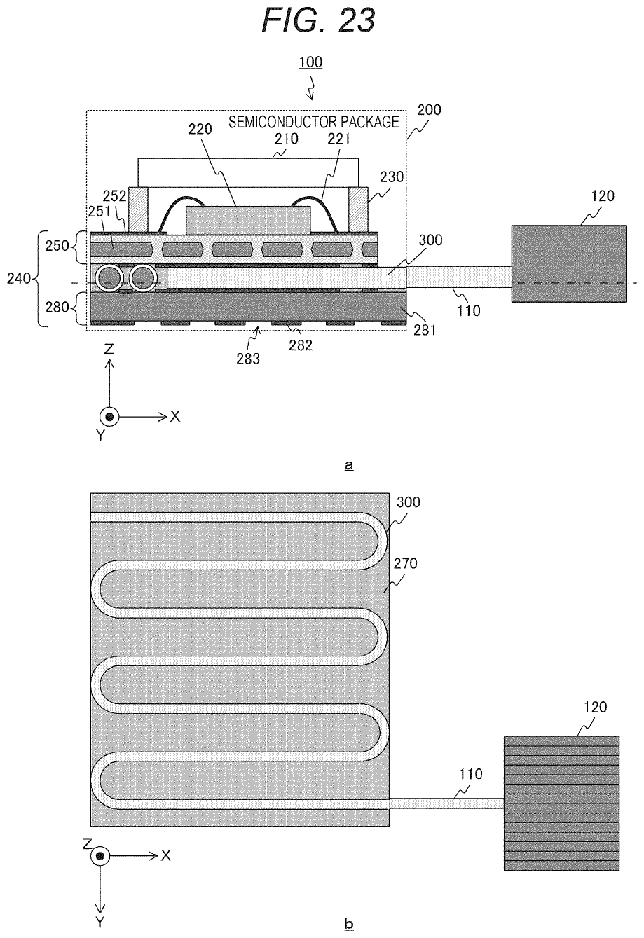

FIG. 23 is an example of a cross-sectional view of the semiconductor device 100 according to the seventh embodiment of the present technology. In FIG. 23, a is an example of a cross-sectional view of the semiconductor device 100 as viewed from the Y axis direction. In FIG. 23, b is an example of a cross-sectional view of the semiconductor device 100 as viewed from the Z axis direction, taken along an alternate long and short dash line in a of FIG. 23. Note that, in b of FIG. 23, a solder ball 271 is omitted.

As depicted in FIG. 23, in the seventh embodiment, a heat pipe 300 is arranged instead of the vapor chamber 260, in a wiring substrate 240. The heat pipe 300 evaporates liquid by heat generated in a semiconductor chip 220 and supplies the evaporated liquid to a heat pipe 110.

As depicted in FIG. 23, by using the heat pipe instead of the vapor chamber 260, it is possible to reduce manufacturing cost.

Furthermore, a thermal conductivity of the heat pipe 300 is theoretically equivalent to that of the vapor chamber 260. Furthermore, when an area where the heat pipe 300 is arranged as viewed from the Z axis direction is reduced, although a thermal conductivity amount is reduced accordingly, the thermal conductivity becomes higher than Cu. However, a thickness of the heat pipe 300 is slightly thicker than the vapor chamber 260.

Note that the second embodiment and the third embodiment can be applied to the seventh embodiment.

In this way, according to the seventh embodiment of the present technology, since the heat pipe is arranged instead of the vapor chamber 260, it is possible to reduce the manufacturing cost.

### 8. Application Example to Mobile Object

The technology according to the present disclosure (present technology) can be applied to various products. For example, the technology according to the present disclosure may be implemented as a device to be mounted on a mobile object of any kind, such as an automobile, an electric automobile, a hybrid electric automobile, a motorcycle, a bicycle, a personal mobility, an airplane, a drone, a ship, or a robot.

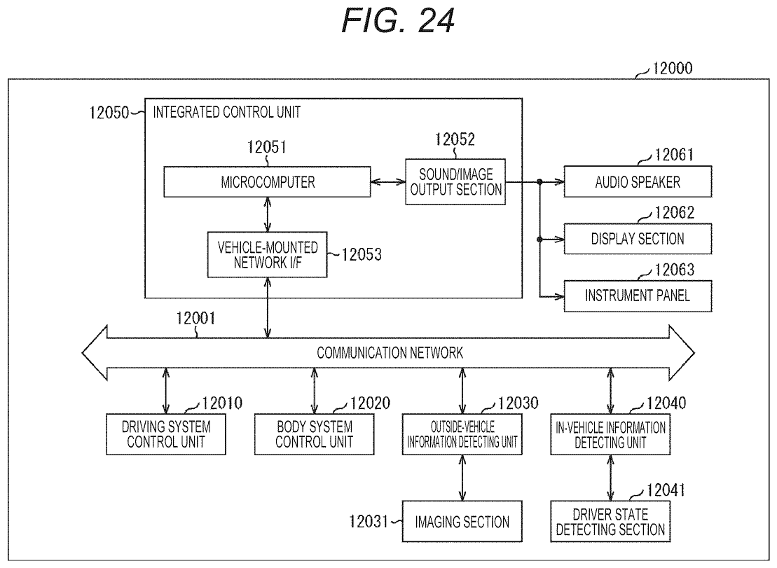

FIG. 24 is a block diagram depicting an example of a schematic configuration of a vehicle control system as an example of a mobile object control system to which the technology according to an embodiment of the present disclosure can be applied.

The vehicle control system 12000 includes a plurality of electronic control units connected to each other via a communication network 12001. In the example depicted in FIG. 24, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are depicted as functional configurations of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 24, an audio speaker 12061, a display section 12062, and an instrument panel 12063 are depicted as the output devices. The display section 12062 may, for example, include at least one of an on-board display and a head-up display.

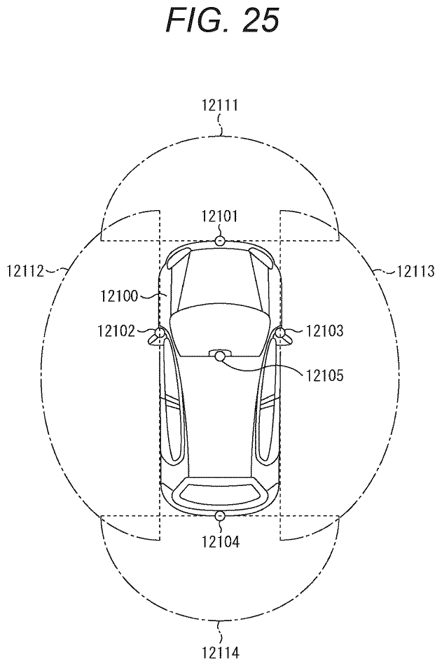

FIG. 25 is a diagram depicting an example of installation positions of the imaging sections 12031.

In FIG. 25, imaging sections 12101, 12102, 12103, 12104, and 12105 are included as the imaging section 12031.

The imaging sections 12101, 12102, 12103, 12104, and 12105 are provided to, for example, positions such as a front nose, a sideview mirror, a rear bumper, a back door, or upper portion of a windshield within the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors mainly obtain images of sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 25 depicts an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure is applicable to the imaging section 12031, for example, among the configurations described above. Specifically, the semiconductor device 100 in FIG. 1 can be applied to the imaging section 12031. By applying the technology according to the present disclosure to the imaging section 12031, it is possible to improve stability and reliability of an operation of the device by improving a heat dissipation performance.

Note that the embodiments described above indicate examples for embodying the present technology, and the respective matters in the embodiments and the respective matters specifying the invention in the claims have correspondence relationships. Similarly, the matters specifying the invention in the claims and the matters with the same names in the embodiment of the present technology have correspondence relationships, respectively. The present technology, however, is not limited to the embodiments, and can be implemented by making various modifications to the embodiments without departing from the scope of the present technology.

Note that the effects described herein are merely examples and are not limited, and other effects may also be achieved.

Note that the present technology may also have the following configurations.
(1) A semiconductor device including:
a semiconductor package in which a semiconductor chip and a wiring substrate that evaporates liquid by heat generated in the semiconductor chip and generates gas are provided;
a heat dissipation member configured to condense the gas into the liquid; and
a connection member configured to supply the gas to the heat dissipation member and reflux the liquid to the wiring substrate.
(2) The semiconductor device according to (1), in which
the wiring substrate includes
a pair of substrates and
a vapor chamber arranged between the pair of substrates.
(3) The semiconductor device according to (2), in which the wiring substrate further includes a mold resin formed around the vapor chamber.
(4) The semiconductor device according to (2) or (3), in which
a counterbore hole is formed in one of the pair of substrates, and
the semiconductor chip is bonded to the vapor chamber via the counterbore hole.
(5) The semiconductor device according to (2), in which
the vapor chamber includes
a gas flow path,
a liquid flow path, and
a through-hole formed around the gas flow path and the liquid flow path.
(6) The semiconductor device according to any one of (1) to (5), in which
the semiconductor chip is connected to the wiring substrate by wire bonding.
(7) The semiconductor device according to any one of (1) to (5), in which
the semiconductor chip is flip-chip mounted on the wiring substrate.
(8) The semiconductor device according to (1), in which
the wiring substrate includes
a pair of substrates and
a heat pipe arranged between the pair of substrates.
(9) A semiconductor package including:
a semiconductor chip; and
a wiring substrate configured to evaporate liquid by heat generated in the semiconductor chip and generate gas.
(10) The semiconductor package according to (9), in which
the wiring substrate evaporates liquid by the heat and generates gas and condenses the gas and generates the liquid.
(11) A method for manufacturing a semiconductor device, including:
a wiring substrate forming procedure for forming a wiring substrate that evaporates liquid by heat generated in a semiconductor chip and generates gas;
a connection procedure for connecting the semiconductor chip to the wiring substrate;
a procedure for joining a connection member that supplies the gas to a heat dissipation member that condenses the gas into the liquid and refluxes the liquid to the wiring substrate to the wiring substrate; and
a procedure for joining the heat dissipation member to the connection member.
(12) The method for manufacturing the semiconductor device according to (11), further including:
a procedure for singulating a semiconductor package including a predetermined number of the wiring substrates, after the connection procedure.

### REFERENCE SIGNS LIST

100 Semiconductor device
110, 300 Heat pipe
111, 261 Gas flow path
112, 262 Liquid flow path
120 Heat sink
200 Semiconductor package
210 Glass
220 Semiconductor chip
221 Wire
230 Frame
240 Wiring substrate
250 Upper substrate
251, 281 Core material
252, 282 Copper foil
260 Vapor chamber
265 Upper lid
265-1 Top cover
265-2 Bottom cover
266 Vent
268 Copper plating
269 Resin
270 Mold resin
271, 291, 292 Solder ball
272 Slit
280 Lower substrate
283 Copper plating hole
285 Lower wafer
293 Adhesive
500 Dicing saw
510 Film
12031 Imaging section

1. A semiconductor device comprising:
a semiconductor package in which a semiconductor chip and a wiring substrate that evaporates liquid by heat generated in the semiconductor chip and generates gas are provided;
a heat dissipation member configured to condense the gas into the liquid; and
a connection member configured to supply the gas to the heat dissipation member and reflux the liquid to the wiring substrate.

2. The semiconductor device according to claim 1, wherein
the wiring substrate includes
a pair of substrates and
a vapor chamber arranged between the pair of substrates.

3. The semiconductor device according to claim 2, wherein the wiring substrate further includes a mold resin formed around the vapor chamber.

4. The semiconductor device according to claim 2, wherein
a counterbore hole is formed in one of the pair of substrates, and
the semiconductor chip is bonded to the vapor chamber via the counterbore hole.

5. The semiconductor device according to claim 2, wherein
the vapor chamber includes
a gas flow path,
a liquid flow path, and
a through-hole formed around the gas flow path and the liquid flow path.

6. The semiconductor device according to claim 1, wherein
the semiconductor chip is connected to the wiring substrate by wire bonding.

7. The semiconductor device according to claim 1, wherein
the semiconductor chip is flip-chip mounted on the wiring substrate.

8. The semiconductor device according to claim 1, wherein
the wiring substrate includes
a pair of substrates and
a heat pipe arranged between the pair of substrates.

9. A semiconductor package comprising:
a semiconductor chip; and
a wiring substrate configured to evaporate liquid by heat generated in the semiconductor chip and generate gas.

10. The semiconductor package according to claim 9, wherein
the wiring substrate evaporates liquid by the heat and generates gas and condenses the gas and generates the liquid.

11. A method for manufacturing a semiconductor device, comprising:
a wiring substrate forming procedure for forming a wiring substrate that evaporates liquid by heat generated in a semiconductor chip and generates gas;
a connection procedure for connecting the semiconductor chip to the wiring substrate;
a procedure for joining a connection member that supplies the gas to a heat dissipation member that condenses the gas into the liquid and refluxes the liquid to the wiring substrate to the wiring substrate; and
a procedure for joining the heat dissipation member to the connection member.

12. The method for manufacturing the semiconductor device according to claim 11, further comprising:
a procedure for singulating a semiconductor package including a predetermined number of the wiring substrates, after the connection procedure.
